(19) United States
(12) Patent Application Publication
(10) Pub. No.: US 2005/0064637 A1
(43) Pub. Date: Mar. 24, 2005

(54) [METHOD OF MANUFACTURING NMOS TRANSISTOR WITH P-TYPE GATE]

(76) Inventor: Wen-Yuan Yeh, Hsinchu County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/708,175

(22) Filed: Feb. 13, 2004

(30) Foreign Application Priority Data
Sep. 23, 2003 (TW) 92126145

(51) Int. Cl. H01L 21/336; H01L 21/8234; H01L 21/4763

(52) U.S. Cl. 438/197; 438/585; 438/592

(57) ABSTRACT

A method of manufacturing an N-channel metal-oxide-semiconductor (NMOS) transistor with a P-type gate is provided. A substrate is provided and then a gate dielectric layer is formed over the substrate. An indium doped polysilicon layer is formed over the gate dielectric layer in an in-situ deposition process. The indium doped polysilicon layer and the gate dielectric layer are patterned to form a gate structure. An N-doped source/drain region is formed in the substrate beside the gate structure to form the P-type gate NMOS transistor. Since the indium doped polysilicon layer is formed in an in-situ deposition process instead of boron implantation, lattice defects in the gate are minimized the problem of penetration for boron ions is solved.

### CROSS REFERENCE TO RELATED APPLICATIONS

This application claims the priority benefit of Taiwan application serial no. 92126145, filed Sep. 23, 2003.

### BACKGROUND OF INVENTION

1. Field of the Invention

The present invention relates to a method of manufacturing a semiconductor device. More particularly, the present invention relates to a method of manufacturing an N-channel metal-oxide-semiconductor (NMOS) transistor with a P-type gate.

2. Description of the Related Art

Metal-oxide-semiconductor (MOS) transistor is one of the most important electronic devices in a very large scale integrated (VLSI) circuit. As the name metal-oxide-semiconductor suggests, a MOS transistor is consisted of three basic materials, namely, metal, oxide and semiconductor. However, modern MOS devices often use polysilicon instead of metal to contact with the oxide layer. Furthermore, a minute amount of dopants is also implanted into the polysilicon layer to lower resistivity to improve its electrical performance. Therefore, a MOS transistor should be regarded as an electronic device constructed using a doped polysilicon layer, a silicon dioxide layer and a silicon substrate.

In general, MOS devices can be classified into three major types including N-channel MOS, P-channel MOS and complementary MOS. The N-channel MOS (NMOS) can be further sub-divided into P-gate NMOS and N-gate NMOS according to the type of dopants implanted into the polysilicon layer. In dynamic random access memory (DRAM) devices, NMOS transistors are frequently used as access switches.

In recent years, advance in semiconductor fabrication technologies has produced devices with feature size down in the sub-micron regime. However, as the dimension of the devices on each chip shrinks so that the gate length of each device is reduced, short channel effect has become an increasingly important, a factor affecting the normal operation of a MOS device. To suppress the short channel effect due to a reduction in gate length, more dopants are implanted into the channel. Yet, an over-abundant supply of dopants inside the channel may lead to an increase in leakage current. When the MOS devices are used as basic elements inside, say, a DRAM unit, too much leakage current may compromise the data retention capacity.

In a conventional DRAM device, a DRAM device using P-gate NMOS transistors require 25% less channel dopants than a DRAM device using N-gate NMOS transistors. In other words, the probability of having a leakage current resulting in a drop in data retention capacity is lowered when P-gate NMOS transistors are used. Another advantage of reducing the channel dopants is a lowering of the electric field strength at a depth roughly 0.4 μm below the top surface of the substrate. However, in the fabrication of a conventional P-gate NMOS, boron ions are typical dopants implanted into the polysilicon layer. During the implantation, some of the energetic ions may break up the crystal to produce lattice defects. In addition, boron ions are also a source that aggravates the leakage problem. Therefore, using boron implantation to form P-gate NMOS transistor often has adverse effects on overall electrical performance of the device.

### SUMMARY OF INVENTION

Accordingly, one objective of the present invention is to provide a method of manufacturing an N-channel metal-oxide-semiconductor (NMOS) transistor with a P-type gate that can improve overall electrical performance.

Another objective of this invention is to provide a method of manufacturing an N-channel metal-oxide-semiconductor (NMOS) transistor with a P-type gate that can reduce the number of crystal lattice defects in a polysilicon layer.

To achieve these and other advantages and in accordance with the purpose of the invention, as embodied and broadly described herein, the invention provides a method of manufacturing an N-channel metal-oxide-semiconductor (NMOS) transistor with a P-type gate. First, a substrate is provided. A gate dielectric layer is formed over the substrate. Thereafter, an indium doped polysilicon layer is formed over the gate dielectric layer. The indium doped polysilicon layer and the gate dielectric layer are patterned to form a gate. Finally, an N-doped region is formed in the substrate on each side of the gate to form the P-type gate NMOS transistor.

According to one preferred embodiment of this invention, the aforementioned method further comprises forming a metal suicide layer over the indium doped polysilicon layer after forming the indium doped polysilicon layer over the gate dielectric layer but before forming patterning the indium doped polysilicon layer and the gate dielectric layer.

In the polysilicon doping process of this invention, indium ions are used instead of the conventional boron ions. Hence, problems caused by boron ions diffusing into the substrate to affect device performance are avoided.

This invention also provides an alternative method of manufacturing an N-channel metal-oxide-semiconductor (NMOS) transistor with a P-type gate. First, a substrate is provided. A gate dielectric layer is formed over the substrate. Thereafter, an indium doped polysilicon layer is formed over the gate dielectric layer. The indium doped polysilicon layer is formed in an in-situ doping operation using indium chloride (InCl₃) as a source of gaseous dopants. The indium doped polysilicon layer and the gate dielectric layer are patterned to form a gate. Finally, an N-doped region is formed in the substrate on each side of the gate to form the P-type gate NMOS transistor.

According to one preferred embodiment of this invention, the aforementioned method further comprises forming a metal suicide layer over the indium doped polysilicon layer after forming the indium doped polysilicon layer over the gate dielectric layer but before forming patterning the indium doped polysilicon layer and the gate dielectric layer.

In the aforementioned polysilicon fabrication process, indium ions are doped into the polysilicon layer in an insitu operation. Hence, the number of lattice defects within the crystalline polysilicon layer is greatly reduced. Furthermore, because chlorine form a relatively strong bond with silicon oxide, using gaseous indium chloride as a source of dopants in the in-situ doping of polysilicon increases the bonding strength between the polysilicon layer and the gate dielectric layer.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A through 1F are schematic cross-sectional views showing the progression of steps of manufacturing an NMOS transistor with a P-type gate according to one preferred embodiment of this invention.

### DETAILED DESCRIPTION

Reference will now be made in detail to the present preferred embodiments of the invention, examples of which are illustrated in the accompanying drawings. Wherever possible, the same reference numbers are used in the drawings and the description to refer to the same or like parts.

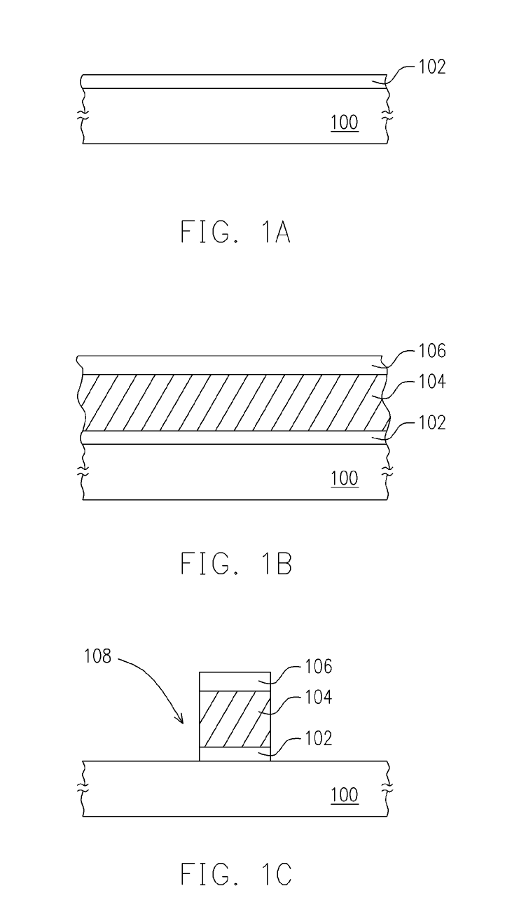

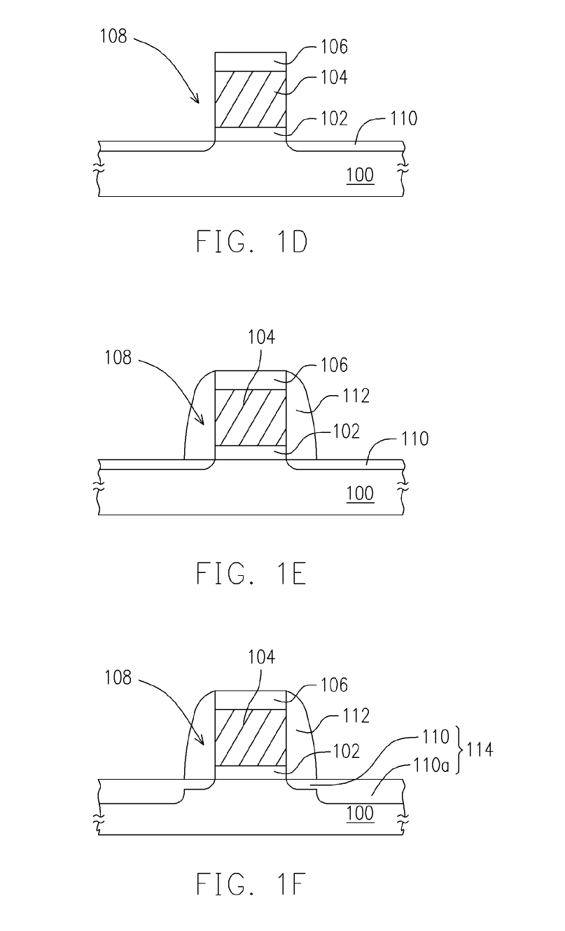

FIGS. 1A through 1F are schematic cross-sectional views showing the progression of steps of manufacturing an NMOS transistor with a P-type gate according to one preferred embodiment of this invention. As shown in FIG. 1A, a substrate 100 such as a P-type substrate is provided. A gate dielectric layer 102 is formed over the substrate 100. The gate dielectric layer 102 is a silicon oxide layer formed, for example, by performing a thermal oxidation process. Obviously, the gate dielectric layer 102 can be fabricated from some other dielectric material using a different fabricating method.

As shown in FIG. 1B, an indium doped polysilicon layer 104 is formed over the gate dielectric layer 102 and then a metal silicide layer 106 is formed over the indium doped polysilicon layer 104. To form the indium doped polysilicon layer 104, a chemical vapor deposition is performed to form an undoped polysilicon layer. Thereafter, an ion implantation is carried out implanting indium ions into the undoped polysilicon layer. Finally, an annealing operation is carried out so that the indium doped polysilicon layer 104 undergoes an internal reorganization to reduce the number of defects within the crystal lattice.

The indium doped polysilicon layer 104 can also be formed by carrying out a chemical vapor deposition with in-situ doping of indium ions. In the in-situ doping process, indium chloride (InCl₃) and silicane (SiH₄) are used as gaseous reactants and nitrogen and argon are used as gas carriers in the chemical vapor deposition process, for example. To form the indium doped polysilicon layer 104, solid indium chloride is heated to a temperature higher than its sublimation temperature (for example, 280° C.) so that solid indium chloride vaporizes to form a gas. Thereafter, gaseous indium chloride is channeled into a chemical vapor deposition chamber where indium ions and polysilicon are deposited over the gate dielectric layer 102 in situ. In addition, the metal silicide layer 106 can be a refractory silicide compound such as tungsten silicide. The metal silicide layer 106 is formed, for example, by performing a chemical vapor deposition operation.

As shown in FIG. 1C, the gate dielectric layer 102, the indium doped polysilicon layer 104 and the metal silicide layer 106 are patterned to form a gate structure 108. The gate dielectric layer 102, the indium doped polysilicon layer 104 and the metal silicide layer 106 are patterned, for example, by conducting a photolithographic and an etching process in sequence.

As shown in FIG. 1D, N-type dopants are implanted into the substrate 100 on each side of the gate structure 108 to form lightly doped regions 110. The lightly doped regions 110 serve as lightly doped drain (LDD) regions in the subsequently formed MOS device. The lightly doped regions 110 are formed, for example, by performing an ion implantation.

As shown in FIG. 1E, spacers 112 are formed on the side-walls of the gate structure 108 such that the spacers 112 also cover a portion of the lightly doped regions 110. The spacers 112 are formed, for example, by performing a chemical vapor deposition to produce a dielectric layer (not shown) over the substrate 100 and then performing an anisotropic etching operation to remove a portion of the dielectric layer.

As shown in FIG. 1F, N-type dopants are implanted into the substrate 100 on each side of the gate structure 108 just outside the spacers 112 to form heavily doped regions 110a. Here, the process for fabricating a P-type gate NMOS transistor is completed. The heavily doped regions 110a are formed, for example, by performing an ion implantation. Each heavily doped region 110a together with a corresponding lightly doped region 110 form a source/drain region 114.

In the aforementioned P-type gate NMOS transistor, the metal silicide layer serves to lower the resistivity of the gate structure and hence its presence is not absolutely essential. In this invention, one may choose to form a metal silicide layer over the indium doped polysilicon layer.

In this invention, an indium doped polysilicon layer replaces the conventional boron doped polysilicon layer as the gate for the NMOS transistor. Since indium ions are harder to diffuse, the P-type gate NMOS transistor has a better electrical performance than the conventional P-type gate NMOS transistor.

It is to be noted that the indium doped polysilicon layer may be formed by performing an in-situ chemical vapor deposition process. Because a doped polysilicon formed in an in-situ process requires no subsequent annealing operation, defects in the crystal lattice due to improper control of the annealing parameters can be avoided. Furthermore, using gaseous indium chloride as a doping source has the added advantage of strengthening the bond between the indium doped polysilicon layer and the silicon oxide layer (the gate dielectric layer) because chlorine atoms have great affinity for silicon oxide.

Furthermore, the P-type gate NMOS transistor of this invention can be applied to form a dynamic random access memory (DRAM). The P-type gate NMOS transistor of this invention is able to boost the data retention capacity of the DRAM because the indium doped polysilicon layer has greater capacity than the conventional boron doped polysilicon layer to prevent leakage.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A method of manufacturing an N-channel metal-oxide-semiconductor (NMOS) transistor with an P-type gate, comprising:
providing a substrate;
forming a gate dielectric layer over the substrate;
forming an indium doped polysilicon layer over the gate dielectric layer by using a chemical vapor deposition process with a gas comprising indium chloride (InCl₃);
patterning the indium doped polysilicon layer and the gate dielectric layer to form a gate; and
forming an N-doped region in the substrate on each side of the gate.

2. The method of claim 1, wherein a gas source for the introduced indium chloride (InCl₃) comprises evaporating solid indium chloride (InCl₃) to form indium chloride vapor before passing the indium chloride vapor into a reaction chamber during the chemical vapor deposition process.

3-7. (canceled).

8. A method of manufacturing an N-channel metal-oxide semiconductor (NMOS) transistor with a P-type gate, comprising:
providing a substrate; forming a gate dielectric layer over the substrate;
performing a chemical vapor deposition process using a gas comprising indium chloride (InCl₃), SiH4, nitrogen and argon to form an indium doped polysilicon layer over the gate dielectric layer;
forming a silicide layer over the indium doped polysilicon layer;
patterning the silicide layer, the indium doped polysilicon layer and the gate dielectric layer to form a gate; and
forming an N-doped region in the substrate on each side of the gate.

9. The method of claim 8, wherein a gas source of the introduced indium chloride (InCl₃) comprises evaporating solid indium chloride (InCl₃) to form indium chloride vapor before introducing the indium chloride vapor into a reaction chamber during the chemical vapor deposition process.

10. The method of claim 9, wherein the step of evaporating solid indium chloride to form a gaseous vapor comprises heating the solid indium chloride to a temperature of about 280° C.

11-20. (canceled).

21. The method of claim 1, further comprising a step of forming a silicide layer over the indium doped polysilicon layer.

22. The method of claim 2, wherein the step of evaporating solid indium chloride to form a gaseous vapor comprises heating the solid indium chloride to a temperature of about 280° C.
